(19) United States
(12) Patent Application Publication
(10) Pub. No.: US 2011/0279990 A1
(43) Pub. Date: Nov. 17, 2011

(54) PRINTED BOARD AND ELECTRONIC EQUIPMENT INCORPORATING THE PRINTED BOARD

(76) Inventor: Makoto Hirano, Kanagawa (JP)

(21) Appl. No.: 13/145,768

(22) PCT Filed: Feb. 26, 2009
(86) PCT No.: PCT/JP2009/000864

§ 371 Date: Jul. 21, 2011

(51) Int. Cl. H05K 1/02

(52) U.S. Cl. 361/777

(57) ABSTRACT

A printed board includes footprints which are electrically solder-bonded to a surface-mounting substrate, on which electronic components are mounted, and which assists the heat release from the surface-mounting substrate. The footprint comprises a fillet-forming division which is placed on an outer-edge side of the surface-mounting substrate and where solder is supplied independently when solder-bonding is performed. The fillet-forming division is solder-bonded to the same electrode as the electrode of the surface-mounting substrate to which the footprint is solder-bonded.

### TECHNICAL FIELD

The present invention relates to a printed board capable of reducing solder failures and electronic equipment incorporating such a printed board.

### BACKGROUND ART

A printed board (printed-wiring board, PWB) on which surface-mountable electronic components (SMDs) are mounted comes with footprints for soldering used to mount the electrodes of the electronic components thereon.

The footprints for soldering, which are formed of copper foil, for instance, provide electrical connection between the printed board and the electronic components. The footprints for soldering also function as thermal conduction paths for releasing the heat produced in the electronic components.

When surface-mountable electronic components are mounted on the printed board, cream solder is transferred and applied onto footprints for soldering by a screen printing using a metal mask. And the electrodes of the electronic components are placed in predetermined positions in such a manner that the footprints on the printed board and the electrodes of the electronic components are connected to each other via the cream solder.

The cream solder is once melted by heating in a reflow furnace and then solidified, thereby connecting the electronic components with the printed board. Therefore, the footprints for soldering are arranged, as appropriate, in conformity to the shapes of leads of the electronic components.

At the same time, along with the increasing complexity and sophistication of the electronic components and wiring structures, there are cases where a surface-mounting substrate mounted with a plurality of electronic components is prepared in advance and then the surface-mounting substrate is soldered to the printed board. A footprint structure of a printed-wiring board that allows soldering of a plurality of electronic components of different sizes to the footprints with accuracy is disclosed in the following Patent Document 1, for instance.
[Patent Document 1] Japanese Unexamined Patent Application Publication No. 2002-329954.

### DISCLOSURE OF INVENTION

### Problems to be Solved by the Invention

In response to the increase in the amount of heat generation resulting from the sophistication and increasing complexity of electronic components, there is a tendency for the enlargement of individual footprints to assist the heat release from the surface-mounting substrate to the printed board. Yet, the enlargement of individual footprints causes an increase in solder feed rate, which in turn may promote maldistribution of solder fed into the footprints. And the occurrence of maldistribution of solder will present a factor in solder failures between the surface-mounting substrate and the printed board.

The present invention has been made in view of the foregoing problems, and a purpose thereof is to provide a printed board and the like having footprints capable of reducing solder failures between a surface-mounting substrate and a printed board.

### Means for Solving the Problem

A printed board according to one embodiment of the present invention includes a footprint which is electrically solder-bonded to a surface-mounting substrate, on which electronic components are mounted, and which assists the heat release from the surface-mounting substrate. The footprint comprises a fillet-forming division which is placed on an outer-edge side of the surface-mounting substrate and where solder is supplied independently when solder-bonding is performed. The fillet-forming division is solder-bonded to the same electrode as an electrode of the surface-mounting substrate to which the footprint is solder-bonded.

Also, the printed board may preferably comprise a plurality of the fillet-forming divisions, and the plurality of fillet-forming divisions may be arranged parallel to an outer edge of the surface mounting substrate on the outer-edge side when the solder-bonding is performed.

Also, in a printed board according to this embodiment, the plurality of fillet-forming divisions may be, more preferably, of the same shape so that an amount of solder supplied independently when the solder-bonding is performed is the same between the plurality of fillet-forming divisions.

Also, a printed board according to this embodiment may, more preferably, include a first fillet-forming division arranged on a predetermined first outer-edge side of the surface-mounting substrate when the solder-boding is performed; and a second fillet-forming division arranged on a second outer-edge side disposed counter to the first outer-side.

Also, in a printed board according to this embodiment, the fillet-forming division may, more preferably, have a constricted portion such that molten solder does not flow out of the fillet-forming division when the solder is independently supplied to perform the solder-bonding.

An electronic apparatus according to another embodiment of the present invention includes: the above-described printed board; and a surface-mounting substrate including an electrode extending in a direction opposite to an outer-edge direction relative to the fillet-forming division when the electrode is solder-bonded to the printed board, wherein the electrode is solder-bonded to the footprint containing the fillet-forming division in a position opposite thereto.

### Advantageous Effects

The prevent invention provides a printed board and the like having footprints that reduce solder failures between a surface-mounting substrate and a printed board.

### BRIEF DESCRIPTION OF DRAWINGS

FIG. 1 is a schematic diagram for explaining the shapes of footprints on a printed board according to a first embodiment.

FIG. 2 is a schematic diagram for explaining an outline of a surface-mounting substrate viewed from a solder-bonding surface side.

FIG. 3 is a schematic diagram for conceptually explaining a structure of an electronic apparatus with a surface-mounting substrate and a printed board solder-bonded to each other.

FIG. 4 is a schematic diagram for explaining a printed board including fillet-forming division groups, each of which is disposed on the opposed outer edges of the printed board.

FIG. 5 shows an exemplary solder surface of a surface-mounting substrate according to a second embodiment.

FIG. 6 is a schematic diagram for explaining a structural outline of an electronic apparatus according to a third embodiment.

FIG. 7 is a schematic diagram showing an exemplary footprint according to a fourth embodiment.

FIG. 8 is a schematic diagram showing a structural outline of an electronic apparatus.

FIG. 9 is a schematic diagram for explaining a maldistribution of solder on an electronic apparatus and so forth.

### EXPLANATION OF REFERENCE NUMERALS

100 Surface-mounting substrate
101 Outer edge
110 Electrode
200 Printed board
210(1) Fillet-forming division
230(1) Footprint

### BEST MODE FOR CARRYING OUT THE INVENTION

A printed board to be described in an exemplary embodiment reduces solder failures between long electrodes for soldering and the corresponding footprints on the printed board when a surface-mounting substrate having long electrodes for soldering on its bottom, which are designed for heat release to the printed board, is mounted thereon.

When the long electrodes for soldering on the surface-mounting substrate and the corresponding long footprints on the printed board are soldered to each other, cream solder must be applied in the amount proportional to the area which is wider than that for short footprints. In other words, the amount of cream solder to be applied per footprint increases when the long electrodes for soldering on the surface-mounting substrate and the long footprints on the printed board are soldered together.

Also, when the cream solder is melted in the reflow process, the flowable area of cream solder, namely, the area equivalent to the area of footprints, is larger for the long footprints than for the short footprints. This tends to cause maldistribution or the like of molten solder, which in turn contributes to the tilting of the surface-mounting substrate at the time of soldering or the occurrence of solder failures without the formation of fillets.

In the present embodiment, therefore, a fillet-forming division is formed by dividing each of the long footprints of the printed board to be soldered to the long electrodes for soldering on a surface-mounting substrate. The fillet-forming division is formed on an outer-edge side of the long axis of a long footprint when the surface-mounting substrate is soldered, and is cut out in a size large enough not to cause maldistribution of molten solder. Also, when the printed board has a plurality of fillet-forming divisions, the arrangement herein should be such that the plurality of fillet-forming divisions are typically in the same shape and arranged parallel to the outer edge thereof.

Thus, the same amount of cream solder is applied to each of the fillet-forming divisions. Also, each fillet-forming division is smaller in area than the long footprint, and the flowable area of molten solder is smaller than that of the footprint before division. Accordingly, the printed board will be such that maldistribution of molten solder can be reduced and fillets can be suitably formed. In other words, the printed board as described in the present embodiment can reduce the faulty forming of fillets and the faulty solder-bonding due to the tilting of the surface-mounting substrate or the like.

Note that in applying cream solder to each of the fillet-forming divisions, a metal mask so made as to conform to the shapes of the respective fillet-forming divisions may be used.

Here, the heat release from the surface-mounting substrate to the printed board will be explained briefly, referring to FIG. 8. FIG. 8 is a schematic diagram showing a structural outline of an electronic apparatus 5000 comprised of a surface-mounting substrate and a printed board. In FIG. 8, the surface-mounting substrate 5100 is bonded to solder 530 on nearly all the surface of an electrode 5130 which is disposed on a substrate 540.

A printed board 5200 is also bonded to the solder 530 on nearly all the surface of a footprint 5220 which is disposed on a substrate resin layer 510. It is to be noted that a substrate resist 520 is disposed around the footprint 5220 in such a manner as to insulate the footprint 5220 against the other footprints and the like.

Ideally, a fillet 535 is formed at an edge of the surface-mounting substrate 5100 when the solder 530 is filled between an electrode 5130 and the footprint 5220 as shown in FIG. 8. The presence or absence of the fillet 535 is an acceptance/rejection criterion in an appearance inspection of soldering, and proper fillet 535 is defined in the standard.

The electronic apparatus 5000 is so designed that the heat generated in the electronic components mounted on the surface-mounting substrate 5100 is released into footprints 5220 via the solder 530. The electronic apparatus 5000 has a not-shown wide-area pattern print formed on the printed board 5200, which provides heat paths allowing thermal conduction from the footprint 5220. Also, the arrangement may be such that the electronic apparatus 5000 has heat paths formed by via holes which effect heat release from the footprints 5220 to an inner print layer.

The electronic apparatus 5000 is of an appropriate heat release structure such that the temperature of the electronic components and the like may not rise above the guaranteed operating temperatures. For more efficient heat release, it is preferable that the electronic apparatus 5000 has larger electrodes 5130 and footprints 5220.

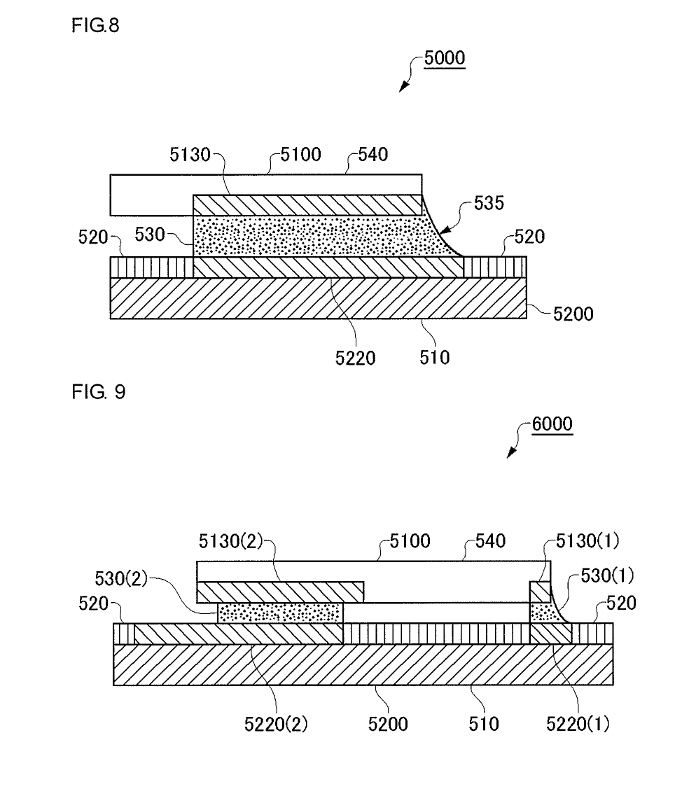

On the other hand, there are cases where maldistribution of solder and the like occur on an electronic apparatus 6000 as shown in FIG. 9. FIG. 9 is a schematic diagram for explaining a maldistribution of solder on the electronic apparatus 6000 and so forth. In FIG. 9, the same reference numerals are used to indicate the parts corresponding to those in FIG. 8.

In the electronic apparatus 6000, a gap is occurring between the surface-mounting substrate 5100 and the printed board 5200 due to the lifting or tilting (so-called seesaw phenomenon) of the surface-mounting substrate 5100. There are also cases where the gap between the surface-mounting substrate 5100 and the printed board 5200 is caused as a consequence of the unevenness of the solder-bonding surface of the substrate 540 or the unevenness or warpage of a substrate resist 520 and the like.

For example, for an electronic apparatus 6000 meeting the North American specifications, there may be cases where a minimum film thickness is required for the substrate resist 520, and therefore the substrate resist 520 may be more likely designed on the thick side. Where the substrate resist 520 is designed on the thick side, the gap between the surface-mounting substrate 5100 and the printed board 5200 tends to be larger due to the substrate resist 520 on the thick side, and in consequence there will be a marked lifting of the surface-mounting substrate 5100.

If there occurs such a marked lifting of the surface-mounting substrate 5100, a prescribed solder supply may not suffice to fill the clearance between an electrode 5130(2) and a footprint 5220(2) especially when more of solder 530(2) is required to fill the clearance between the long electrode 5130(2) and the long footprint 5220(2) disposed counter to the electrode 5130(2). The shortage of solder 530(2) like this will be greater in proportion to the size of area of the electrode 5130(2) or the footprint 5220(2) and the degree of lifting in addition.

The shortage of solder 530(2), if any, will result in an inability to fill the clearance between the electrode 5130(2) and the footprint 5220(2), which in turn creates gaps between the electrode 5130(2) and the footprint 5220(2). The solder 530(2) tends to condense in the central area of the footprint 5220(2) under its own surface tension. Accordingly, the gaps between the electrode 5130(2) and the footprint 5220(2) will more likely occur in peripheral regions of the footprint 5220(2) as shown in FIG. 9.

Also, as shown in FIG. 9, the solder 530(2) between the electrode 5130(2) and the footprint 5220(2) cannot form fillets, which will lead to a rejection in the appearance inspection of soldering.

On the other hand, solder 530(1) between a relatively short electrode 5130(1) and a footprint 5220(1) will have a formation of satisfactory fillet because the fillet is less influenced by the lifting of the surface-mounting substrate 5100. Between the relatively short electrode 5130(1) and the footprint 5220(1), there will be a relatively minor shortage, if any, of the solder 530(1). Hence, it is conceivable that there is a greater force for preventing condensation of the solder 530(1) because of the fillet formed between the electrode 5130(1) and the footprint 5220(1) than the force for condensation thereof under its surface tension. Thus the solder 530(1) can remain in the same positions as it is supplied.

As a result, there are fewer occurrences of solder failures between the electrode 5130(1) and the footprint 5220(1) than between the electrode 5130(2) and the footprint 5220(2).

It is to be noted that any attempt at bonding the surface-mounting substrate 5100 and the footprint 5220 to each other, for instance, with the purpose of lessening the lifting of the surface-mounting substrate 5100 may contribute to an increased lifting thereof with the adhesive itself acting as a new resin layer. Note also that unless otherwise stated, a footprint as used in the embodiments herein refers to a footprint on the printed board corresponding to a single continuous electrode on the solder-bonding surface of the surface-mounting substrate.

### First Embodiment

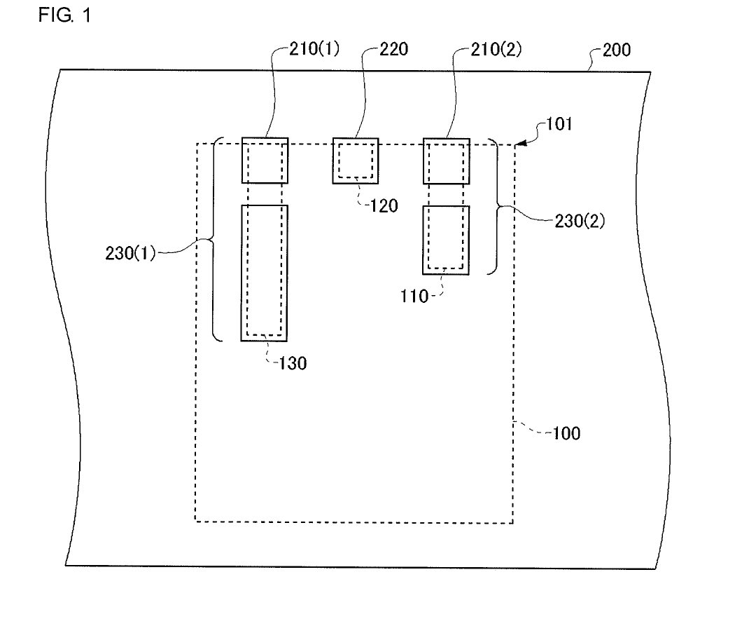

FIG. 1 is a schematic diagram for explaining the shapes of footprints on a printed board 200 according to a first embodiment. Shown in FIG. 1 is an outline of the printed board 200 viewed from a solder-bonding surface side. The printed board 200 is provided with footprints 230(1), 220, and 230(2).

A surface-mounting substrate 100 is solder-bonded to the printed board 200. The surface-mounting substrate 100 is provided with electrodes 130, 120, and 110 in such a manner that they correspond respectively to the footprints 230(1), 220, and 230(2).

To effect an efficient heat release from the surface-mounting substrate 100, the heat of the surface-mounting substrate 100 is transferred to the printed board 200 via the footprints 230(1), 220, and 230(2).

Also, for an efficient transfer of the heat generated in the surface-mounting substrate 100 to the printed board 200, the electrodes 130, 120, and 110 of the surface-mounting substrate 100 are typically formed larger than when only electrical connection is intended. In a similar manner, to effect an easier transfer of the heat generated in the surface-mounting substrate 100, the footprints 230(1), 220, and 230(2) corresponding respectively to the electrodes 130, 120, and 110 of the surface-mounting substrate 100 are typically formed larger than when only electrical connection is intended.

Also, the footprint 230(1) corresponding to the electrode 130 of the surface-mounting substrate 100 is provided with a fillet-forming division 210(1). Solder is supplied independently to the fillet-forming division 210(1) when solder-bonding is performed.

The fillet-forming division 210(1), which has a flowable area of solder smaller than the whole of the footprint 230(1), can prevent maldistribution of molten solder. It is also possible to consider the fillet-forming division 210(1) as a part of the footprint 230(1), which is to be primarily formed as a single piece, cut out into a size that may not allow maldistribution of solder.

The fillet-forming division 210(1) is formed by dividing the long axis of the footprint 230(1) such that the fillet-forming division 210(1) is disposed on an outer-edge 101 side of the surface-mounting substrate 100. Also, since the fillet-forming division 210(1) is of such size as to form a fillet satisfactorily, it is possible, for instance, to reduce rejections of soldering from the outer-edge 101 side in the appearance inspection.

Also, the footprint 230(2) corresponding to the electrode 110 of the surface-mounting substrate 100 is provided with a fillet-forming division 210(2). Solder is supplied independently to the fillet-forming division 210(2) when solder-bonding is performed.

The fillet-forming division 210(2), which has a flowable area of solder smaller than the whole of the footprint 230(2), can prevent maldistribution of molten solder. It is also possible to consider the fillet-forming division 210(2) as a part of the footprint 230(2), which is to be primarily formed as a single piece, cut out into a size that may not allow maldistribution of solder.

The fillet-forming division 210(2) is formed by dividing the long axis of the footprint 230(2) such that the fillet-forming division 210(2) is disposed on the outer-edge 101 side of the surface-mounting substrate 100. Since the fillet-forming division 210(2) is of such size as to form a fillet satisfactorily, it is possible, for instance, to reduce rejections of soldering from the outer-edge 101 side in the appearance inspection.

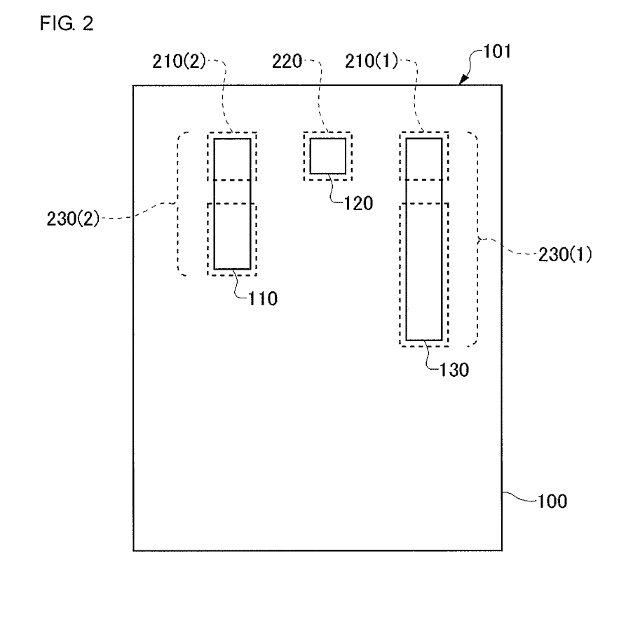

FIG. 2 is a schematic diagram for explaining an outline of the surface-mounting substrate 100 viewed from a solder-bonding surface side. The surface-mounting substrate 100 is provided with the electrodes 110, 120, and 130 to be soldered. And the footprint 230(2) is solder-bonded to the electrode 110. Also, the footprint 230(2) is provided with the fillet-forming division 210(2).

Also, the footprint 230(1) is solder-bonded to the electrode 130. The footprint 230(1) is also provided with the fillet-forming division 210(1). It is preferable that the fillet-forming division 210(1) is of the same shape and size as the fillet-forming division 210(2).

This assures not only the same amount of solder application for both the fillet-forming division 210(1) and the fillet-forming division 210(2), but also the same condition and flowable area of molten solder therefor. Thus a process management of soldering becomes easier, thereby contributing to the reduction in solder failures.

Also, the electrode 120 is solder-bonded to the footprint 220. It is to be considered that the footprint 220, which is shorter than the footprint 230(1) or 230(2) and of such a size as to facilitate satisfactory fillet forming, may hardly cause solder failure without being divided. Also, preferably, the fillet-forming division 210(1) and the fillet-forming division 210(2) are of the same shape and size as the footprint 220.

This assures not only the same amount of solder application for all of the fillet-forming division 210(1), the fillet-forming division 210(2), and the footprint 220, but also the same condition and flowable area of molten solder therefor. Thus the process management of soldering becomes easier, thereby contributing to the reduction in solder failures.

Also, the fillet-forming division 210(1), the fillet-forming division 210(2), and the footprint 220 may preferably be disposed on the side of and in parallel with an outer edge 101 of the surface-mounting substrate 100 as it is soldered, so that soldering of the surface-mounting substrate 100 and the printed board 200 may be performed easily in parallel with each other. And, more preferably, the fillet-forming division 210(1), the fillet-forming division 210(2), and the footprint 220 may be disposed evenly spaced apart, so that soldering of the surface-mounting substrate 100 and the printed board 200 may be performed easily in parallel with each other.

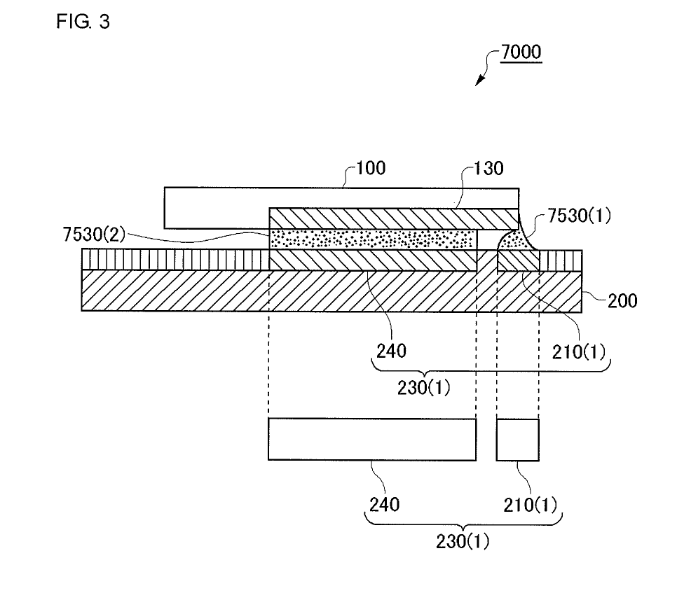

FIG. 3 is a schematic diagram for conceptually explaining a structure of an electronic apparatus 7000 with the surface-mounting substrate 100 and the printed board 200 solder-bonded to each other. In FIG. 3, the electrode 130 on the surface-mounting substrate 100 is bonded to a division remainder 240 of the footprint 230(1) via solder 7530(2). The electrode 130 on the surface-mounting substrate 100 is also bonded to the fillet-forming division 210(1) of the footprint 230(1) via solder 7530(1).

As shown in FIG. 3, the solder 7530(1) on the fillet-forming division 210(1) can form a fillet satisfactorily because the amount of solder is not much and the flowable range of molten solder is limited to the surface of the fillet-forming division 210(1).

If the footprint 230(1) were not divided into the fillet-forming division 210(1) and the division remainder 240, the molten solder on the fillet-forming division 210(1) would flow freely onto the division remainder 240. Also, gravitational effect due to a slightest tilting or condensing force due to surface tension surpasses the fluidity restraining force because of the increased amount of molten solder on the footprint 230(1). This may consequently cause maldistribution of the molten solder.

If the molten solder on the fillet-forming division 210(1) having flowed freely onto the division remainder 240 should be allowed to solidify, a rejection in the appearance inspection would follow without the formation of a fillet.

It should be noted that the footprint 230(1), which is comprised of the fillet-forming division 210(1) and the division remainder 240, is to be primarily formed as a single footprint as mentioned earlier, and therefore the electrode in opposition to the footprint 230(1) at the time of soldering is a single electrode 130.

In other words, the fillet-forming division 210(1) and the division remainder 240 will be electrically connected to each other after the soldering of the surface-mounting substrate 100. Also, the fillet-forming division 210(1) and the division remainder 240, as part of the footprint 230(1), carry out the function of heat release from the single electrode 130 together.

### Second Embodiment

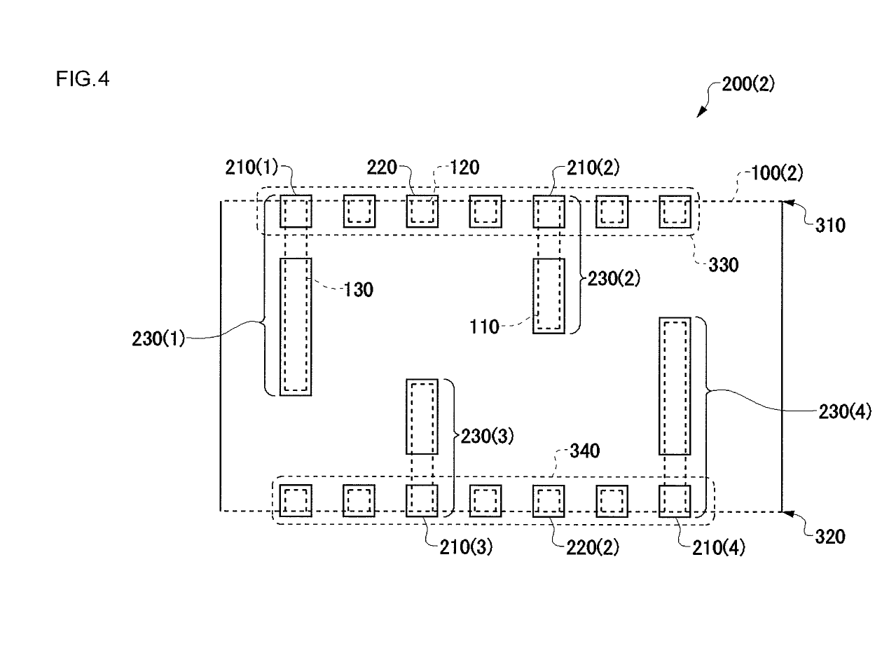

FIG. 4 is a schematic diagram for explaining a printed board 200(2) including fillet-forming division groups 330 and 340, each of which is disposed on the opposed outer edges of the printed board 200(2). In FIG. 4, the components equivalent to those already explained in the first embodiment are given the identical reference numerals and the repeated description thereof is omitted here.

The printed substrate 200(2) according to a second embodiment includes a group of fillet-forming divisions 330 arranged on an outer-edge 310 side and a group of fillet-forming divisions 340 arranged on an outer-edge 320 side disposed counter to the outer edge 310.

Assume herein that the outer edge 310 and the outer edge 320 are each an outer edge of the surface-mounting substrate 100(2) when the surface-mounting substrate 100(2) is soldered to the printed board 200(2). In order that the surface-mounting substrate 100(2) can be soldered satisfactorily to the printed board 200(2) without having the surface-mounting substrate 100(2) tilted against the printed board 200(2), the fillet-forming division groups 330 and 340 are provided at predetermined edges of a region opposite to the surface-mounting substrate 100(2) at the time of soldering.

The group of fillet-forming divisions 330 includes fillet-forming divisions 210(1) and 210(2) and footprints 220 which are of the same shape and size as the fillet-forming divisions 210(1) and 210(2). The group of fillet-forming divisions 330 may have an arbitrary number of (a plurality of) footprints 220. The fillet-forming divisions 210(1) and 210(2) are formed by dividing the long axes of the footprints 230(1) and 230(2), respectively, such that the fillet-forming divisions 210(1) and 210(2) are disposed on the outer-edge side 310 of the surface-mounting substrate 100(2) at the time of soldering.

An electrode 130 is solder-bonded to the footprint 230(1). An electrode 110 is solder-bonded to the footprint 230(2). An electrode 120 is solder-bonded to the footprint 220.

Also, the group of fillet-forming divisions 340 includes fillet-forming divisions 210(3) and 210(4) and footprints 220(2) which are of the same shape and size as the fillet-forming divisions 210(3) and 210(4). The group of fillet-forming divisions 340 may have an arbitrary number of (a plurality of) footprints 220(2). The fillet-forming divisions 210(3) and 210(4) are formed by dividing the long axes of the footprints 230(3) and 230(4), respectively, such that the fillet-forming divisions 210(3) and 210(4) are disposed on the outer-edge side 320 of the surface-mounting substrate 100(2) at the time of soldering.

Also, the respective electrodes of the surface-mounting substrate 100(2) in opposition to the footprint 230(3), the footprint 230(4) and the footprint 220(2) are solder-bonded to the footprint 230(3), the footprint 230(4) and the footprint 220(2).

According to the printed board 200(2) of the second embodiment, fillets are formed in the fillet-forming division groups 330 and 340 provided on the outer-edge 310 side and the outer edge 320 side, respectively, when the surface-mounting substrate 100(2) is solder-bonded. Thus, the soldering can be performed smoothly and evenly.

In other words, the printed board 200(2) includes the group of fillet-forming divisions 330 having a plurality of fillet-forming divisions 210(1) and 210(2) of such size and shape that the fillets can be satisfactorily formed on the outer-edge side 310 under the same condition when the surface-mounting substrate 100(2) is soldered.

Also, the printed board 200(2) includes the group of fillet-forming divisions 340 having a plurality of fillet-forming divisions 210(3) and 210(4) of such size and shape that the fillets can be satisfactorily formed on the outer-edge side 320 under the same condition when the surface-mounting substrate 100(2) is soldered. Also, the fillet-forming division group 330 and the fillet-forming division group 340 may each be provided in two or more thereof. For example, they may be provided corresponding respectively to the outer-edge sides of the four sides of the surface-mounting substrate 100(2). Provision of the fillet forming division groups 330 at an increased number of the corresponding outer edges allows more reliable and stable soldering of the surface-mounting substrate 100(2), which is more desirable.

Also, the fillet-forming division group 330 and the fillet-forming division group 340 each includes a plurality of fillet-forming divisions of same size and shape such that the fillets can each be satisfactorily formed under the same condition.

Thus, the solder failures can be suppressed and the soldering of the surface-mounting substrate 100(2) can be stably performed even if the printed board 200(2) includes the footprints of various (longer and shorter) sizes and various shapes.

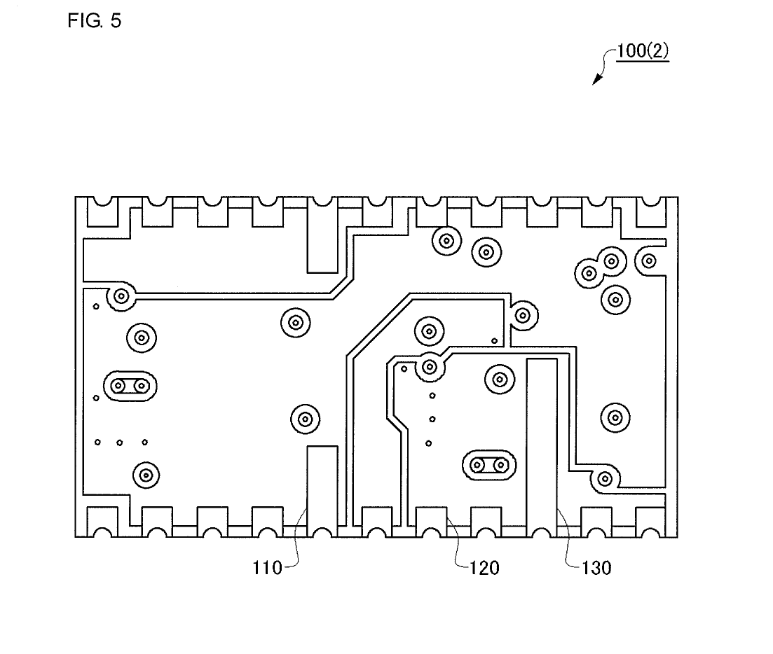

FIG. 5 shows an exemplary solder surface of the surface-mounting substrate 100(2) according to the second embodiment. As shown in FIG. 5, the surface-mounting substrate 102(2) is provided with a plurality of relatively short electrodes 120, a slightly long electrode 110 and a further long electrode 130. A plurality of the relatively short electrodes 120 are arranged at outer edges along the long sides of the surface-mounting substrate 100(2) disposed counter to each other.

It is expected that the slightly long electrode 110 and the further long electrode 130 are much higher in thermal conductance than the relatively short electrodes 120. On the other hand, the plurality of relatively short electrodes 120, the slightly long electrode 110 and the further long electrode 130 are expected to differ in their solder bonding areas when soldered, respectively. Hence, the effect of force with the molten solder differs per electrode. This means that it is comparatively difficult to perform the solder bonding in such a manner that the surface-mounting substrate 100(2) is not tilted as a whole maintaining balance.

Accordingly, it is preferable that the footprints 230(2) and 230(1) disposed counter to the slightly long electrode 110 and the further long electrode 130 at the time of solder, respectively, have the fillet-forming divisions 210(2) and 210(1) of the same size and shape as the footprint 220 disposed counter to the relatively short electrode 120.

The surface-mounting substrate 100(2) can achieve a harmonized balance between the heat release from the surface-mounting substrate 100(2) to the printed board 200(2), the electrical connection and the reduction of soldering failures. Thus, the surface-mounting substrate 100(2) may produce surface-mounting components such as ICs and power supply modules consuming large power. The surface-mounting substrate 100(2) may be especially a surface-mounting substrate of leadless shape type which is so-called one with no stand-off.

By employing the printed board 200(2) according to the second embodiment, the failures at the time of soldering can be reduced and the throughput of a soldering process can be improved without adding new components, thereby contributing to the cost reduction in the electronic equipment.

### Third Embodiment

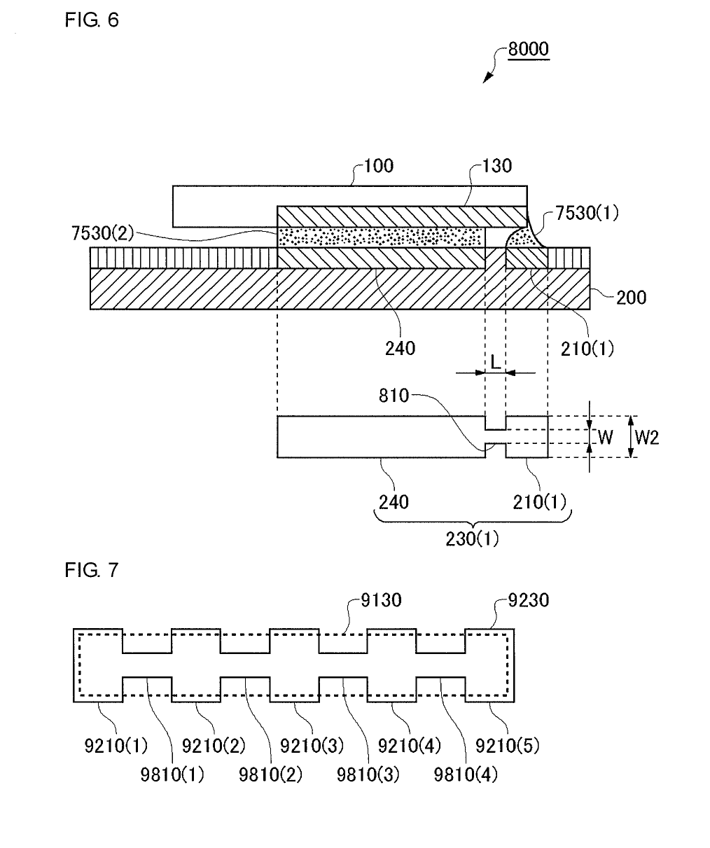

FIG. 6 is a schematic diagram for explaining a structural outline of an electronic apparatus 8000 according to a third embodiment. In FIG. 6, the components equivalent to those already indicated in the electronic apparatus 7000 of FIG. 3 are given the identical reference numerals and the repeated description thereof is omitted here.

As shown in FIG. 6, the printed board 200 in the electronic apparatus 8000 includes a fillet-forming division 210(1) and a division remainder 240 which are components resulting from the division of the footprint 230(1). In the electronic apparatus 8000, the fillet-forming division 210(1) has a constricted portion 810 of length L and width W such that the solder does not flow or move. In other words, the fillet-forming division 210(1) is connected to the division remainder 240 through the medium of the constricted portion 810.

In this case, from the viewpoint of suppressing the movement of solder in the constricted portion 810, it is preferable that the width W of the constricted portion 810 be about 0.5 mm to about 1.0 mm. If the width W of the constricted portion 810 becomes less than 0.5 mm, the effect of suppressing the movement of solder will tend to decrease due to a capillary phenomenon. It is desirable that the width W2 of the footprint 230(1) be at least larger than 1.0 mm.

Accordingly, it is desirable that the width W of the constricted portion 810 be set to a value at least larger than 0.5 mm. It is desirable that the length L of the constricted portion 810 be greater than or equal to twice as long as the width W thereof. Typically, the length L of the constricted portion 810 may be in a range of about 1.0 mm to 2.0 mm.

By employing the electronic apparatus 8000 according to the third embodiment, the solder failures at the time the surface-mounting substrate 100 is soldered to the printed board 200 can be reduced. Also, since the electrical connection and the thermal conductivity are assured by the provision of the constricted portion 810, the stability of electrical connection and the heat radiation performance can be improved.

### Fourth Embodiment

A footprint 9230 to be explained in a fourth embodiment includes five fillet-forming divisions 9210(1) to 9210(5). Also, the footprint 9230 to be described in the fourth embodiment includes four constricted portions 9810(1) to 9810(4) (hereinafter referred to as “constricted portion 9810” or “constricted portions 9810” as appropriate) between the five fillet-forming divisions 9210(1) to 9210(5) (hereinafter referred to as “fillet-forming division 9210” or “fillet-forming divisions 9210”, as appropriate).

FIG. 7 is a schematic diagram showing an exemplary footprint 9230 according to the fourth embodiment. As shown in FIG. 7, the footprint 9230 may have an arbitrary number of (a plurality of) fillet-forming divisions 9210. It is preferable that a plurality of fillet-forming divisions 9210 be provided at the outer-edge side if at all possible. However, the present embodiment is not limited thereto and, for example, the plurality of fillet-forming divisions 9210 may be placed at arbitrary positions.

Each of the fillet-forming divisions 9210 in the footprint 9230 is preferably of the same shape and the same size. This allows the amount of solder supplied to each fillet-forming division 9210 to be identical and makes it easy to solder the surface-mounting substrate horizontally on the electrodes 9130.

Also, an arbitrary number of constricted portions 9810 may be provided between each fillet-forming division 9210. The constricted portion 9810 is preferably of such length and width that the solder cannot flow or move. The suitable length and width of the constricted portion 9810 vary depending on the soldering characteristic and soldering condition and therefore they may be designed appropriately according to the specifications required by an electronic apparatus.

The footprint 9230 described in the fourth embodiment may be provided in the electronic apparatus or printed board described in the above-described other embodiments. Since the footprint 9230 described in the fourth embodiment is provided with a plurality of fillet-forming divisions 9210, the stability of the surface-mounting substrate soldered can be improved with respect to the long axis direction of the footprint 9230. Also, since the footprint 9230 described in the fourth embodiment is provided with a plurality of fillet-forming divisions 9210, the fillet is formed at each of the fillet-forming divisions 9210 and therefore the solder failure can be reduced at each thereof.

By employing the electronic apparatus and the printed board as described in each of the embodiments, the solder failures can be reduced without adding a processing for the surface-mounting substrate and without adding new components to the surface-mounting substrate. Also, the solder failures in the electronic apparatus can be reduced in the event of any lifting and/or tilting occur in the surface-mounting board.

Electronic apparatuses where the throughput of the soldering process has been improved can be produced without practically altering and reforming the surface-mounting substrate required by a customer to be mounted thereon and the like or a commercially available surface-mounting substrate. Any given number of plural footprints 9230 may be provided on the printed circuit.

The electronic apparatus, the printed board and so forth described in each of the above-described embodiments are not limited to those described in the above-described embodiments only. It is to be understood that changes and variations in structure and processes may be made without departing from the spirit or scope of the appended claims.

Also, the electronic apparatus, the printed board and the like described in each of the above-described embodiments are not limited to those described in the above-described embodiments only, and may be those realized by combining the structure and/or operation among the above-described embodiments. Note that, in the above-described embodiments, descriptions have been given of an example, for simplicity of explanation, where a packaging device which is soldered to the printed board is the surface-mounting substrate. However, this should not be considered as limiting and, for example, the present embodiments may be applicable to a case where various types of surface-mounting components are mounted on the printed board. That is, the surface-mounting substrate mentioned in the present embodiments may be any mounted device as long as it has such an electrode area as to carry out the functions of heat release and electrical conduction in the solder surface between the surface-mounting substrate and the printed board.

### INDUSTRIAL APPLICABILITY

The present invention is applicable to electronic equipment and the like that mount a surface-mounting substrate that has a relatively long electrode on a solder-bonding surface and does not have the stand-off.

1. A printed board including a footprint which is electrically solder-bonded to a surface-mounting substrate, on which electronic components are mounted, and which assists the heat release from the surface-mounting substrate,
wherein the footprint comprises a fillet-forming division which is placed on an outer-edge side of the surface-mounting substrate and where solder is supplied independently when solder-bonding is performed, and
wherein the fillet-forming division is solder-bonded to the same electrode as an electrode of the surface-mounting substrate to which the footprint is solder-bonded.

2. The printed board according to claim 1,
wherein the printed board comprises a plurality of the fillet-forming divisions, and
wherein the plurality of fillet-forming divisions are arranged parallel to an outer edge of the surface mounting substrate on the outer-edge side when the solder-bonding is performed.

3. The printed board according to claim 2, wherein the plurality of fillet-forming divisions are of the same shape so that an amount of solder supplied independently when the solder-bonding is performed is the same between the plurality of fillet-forming divisions.

4. The printed board, according to claim 1, including:
a first fillet-forming division arranged on a predetermined first outer-edge side of the surface-mounting substrate when the solder-boding is performed; and
a second fillet-forming division arranged on a second outer-edge side disposed counter to the first outer-side.

5. The printed board according to claim 1, wherein the fillet-forming division has a constricted portion such that molten solder does not flow out of the fillet-forming division when the solder is independently supplied to perform the solder-bonding.

6. An electronic apparatus, comprising:
the printed board according to claim 1; and
a surface-mounting substrate including an electrode extending in a direction opposite to an outer-edge direction relative to the fillet-forming division when the electrode is solder-bonded to the printed board,
wherein the electrode is solder-bonded to the footprint containing the fillet-forming division in a position opposite thereto.
